(19) United States
(12) Patent Application Publication
(10) Pub. No.: US 2007/0024364 A1
(43) Pub. Date: Feb. 1, 2007

(54) AMPLIFIER AND AMPLIFICATION METHOD

(76) Inventors: Akira Yasuda, Tokyo (JP); Toru Ido, Ishehara-shi (JP)

Correspondence Address: TEXAS INSTRUMENTS INCORPORATED, P O BOX 655474, M/S 3999, DALLAS, TX, 75265, US

(21) Appl. No.: 11/425,753

(22) Filed: Jun. 22, 2006

(30) Foreign Application Priority Data
Jun. 22, 2005 (JP) 2005-182190

(51) Int. Cl. H03F 3/68

(52) U.S. Cl. 330/124 R

(57) ABSTRACT

An amplifier having an increased the upper limit on the amplitude of an audio signal generated between one common terminal and the output terminals of left and right channels without raising the power supply voltage. The level at common terminal C is changed corresponding to the average of the input audio signals (ViL, ViR) to increase the amplitudes of the output audio signals (VL, VR). In this way, the amplitudes of audio signals (VL, VR) supplied to the headphone can be increased compared with the case when the level at terminal C is kept constant. Also, the upper limit on the amplitudes of audio signals (VL, VR) can be increased without raising the power supply voltage.

### FIELD OF THE INVENTION

The present invention pertains to an amplifier and amplification method used for amplifying plural audio signals. For example, the present invention pertains to an amplifier and amplification method used for amplifying the audio signals supplied to the headphone of a stereo.

### BACKGROUND OF THE INVENTION

Three wires are usually used to connect an amplifier to the headphone of a stereo. These three wires are the two signal wires corresponding to the audio signals of the left and right channels and one ground wire used for supplying the common ground potential. It is also possible to use one ground wire for each of the left and right channels. However, one common wire is usually used in order to reduce the number of wires and the number of connectors.

FIG. 5 shows an example of the general configuration of an amplifier used for a headphone. The amplifier shown in FIG. 5 has amplifying circuit 1 for the left channel, amplifying circuit 2 for the right channel, capacitors 5, 6, 9, 10, and resistors 7, 8. Resistors 7, 8 are connected in series between the supply wire of power supply voltage VDD (referred to as VDD wire hereinafter) and the supply wire of ground potential GND (referred to as GND wire hereinafter). Resistors 7, 8 have the same resistance. A voltage of ‘VDD/2’ is generated at the connection point of the two resistors.

Amplifying circuits 1 and 2 amplify the AC components of the audio signals with voltage ‘VDD/2’ generated at the middle connection point of resistors 7 and 8 used as the DC reference level. Amplifying circuit 1 amplifies the AC component of audio signal Sin_L of the left channel input via capacitor 5. Amplifying circuit 2 amplifies the AC component of audio signal Sin_R of the right channel input via capacitor 6. The output of amplifying circuit 1 is connected to the signal wire of left speaker 3 via capacitor 9. The output of amplifying circuit 2 is connected to the signal wire of the right speaker 4 via capacitor 10. The GND wire of the amplifier is connected to the common ground wire of left and right speakers 3, 4.

Amplifying circuits 1, 2 amplify the AC components of audio signals Sin_L, Sin_R, respectively; with voltage ‘VDD/2’ used as the DC reference level. The audio signals amplified by amplifying circuits 1, 2 vary in a range up to ‘±VDD/2’ with voltage ‘VDD/2’ as the center. In the audio signals amplified by amplifying circuits 1, 2, the DC component ‘VDD/2’ is removed by capacitors 9, 10. Only the AC component is supplied to the left and right speakers 3, 4.

FIG. 6 shows another example of the general configuration of an amplifier used for a headphone. In the amplifier shown in FIG. 6, capacitors 9, 10 in the amplifier shown in FIG. 5 used for eliminating the DC components are removed. Instead, a buffer amplifier 11 that drives the common ground wire of speakers 3, 4 is added. Buffer amplifier 11 supplies a voltage ‘VDD/2’ to the common ground wire of speakers 3, 4 based on the voltage ‘VDD/2’ generated at the middle connection point of resistors 7, 8.

The audio signals amplified by amplifying circuits 1, 2 are supplied to the signal wires of the left and right speakers 3, 4 without going through a capacitor. The DC component of the audio signals supplied to the signal wires is ‘VDD/2’. Therefore, the voltage supplied from buffer amplifier 11 to the common ground wire is also ‘VDD/2’. Consequently, with the DC component ‘VDD/2’ removed from the audio signals output from amplifying circuits 1, 2, only the AC components are supplied to the left and right speakers 3, 4.

The amplifiers shown in FIGS. 5, 6 are equipped with amplifying circuits 1, 2 used for amplifying the left and right audio signals. The audio signals amplified by said amplifying circuits 1, 2 are supplied to the left and right speakers 3, 4. The common ground wire of left and right speakers 3, 4 is kept at a constant potential (ground potential GND or ‘VDD/2’). Since amplifying circuits 1, 2 are operated by a single power supply voltage VDD, the maximum amplitude of the audio signals supplied to speakers 3, 4 is limited to ‘VDD/2’.

For the amplifiers shown in FIGS. 5 and 6, since the amplitude of the audio signals supplied to speakers 3, 4 is limited to half of the power supply voltage VDD, the amplitude of the audio signals supplied to speakers 3, 4 cannot be increased sufficiently. In order to increase the upper limit of the amplitude of the audio signals, the power supply voltage VDD must be increased. This hinders reduction of the power consumption of the circuit.

A general object of the present invention is to solve this problem by providing an amplifier that can increase the upper limit of the amplitude of plural amplified signals generated between one common terminal and plural output terminals without raising the power supply voltage.

### SUMMARY OF THE INVENTION

This and other features and objects are attained, in accordance with one aspect of the present invention by an amplifier that generates plural amplified signals corresponding to plural input signals between one common terminal and plural output terminals, having plural amplifying parts, each of which amplifies one of the plural input signals and outputs the amplified signal to one of the plural output terminals. A signal generating part generates a common signal that changes the level at the common terminal corresponding to the average of the plural input signals to increase the amplitudes of the plural amplified signals. According to this aspect of the present invention described above, the level at the common terminal varies to increase the amplitudes of the plural amplified signals corresponding to the average of the plural input signals. In this way, the upper limit on the amplitude of the amplified signal can be increased compared with the case where the level at the common terminal is kept constant.

Each of the amplifying parts may have an error amplifying part that amplifies the error between the input signal and a feedback signal and outputs the amplified error to an output terminal and a feedback part that outputs a signal obtained by attenuating the amplitude of the amplified signal generated between the output terminal and the common terminal by a prescribed attenuation rate as the feedback signal, and negative feedback is controlled to reduce the difference between the input signal and the feedback signal.

Or, each of the amplifying parts may have an error amplifying part that amplifies the error between the input signal and a feedback signal, a first pulse generating part that generates a first pulse signal corresponding to the signal output from the error amplifying part and outputs the first pulse signal to an output terminal, and a feedback part that outputs a signal obtained by attenuating the amplitude of the amplified signal generated between the output terminal and the common terminal by a prescribed attenuation rate as the feedback signal. Negative feedback is controlled to reduce the difference between the input signal and the feedback signal.

In this case, the signal generating part has a second pulse generating part, which generates a second pulse signal corresponding to the average of the output signals of the error amplifying parts included in the plural amplifying parts and outputs the second pulse signal to the aforementioned common terminal. The first pulse generating part can compare the signal output from the error amplifying part with a prescribed threshold value and switch the level of the output signal to a first level or a second level corresponding to the comparison result. The second pulse generating part can compare the average of the output signal of the error amplifying part included in each of the plural amplifying parts with a prescribed threshold value and switch the level of the output signal to the first or second level corresponding to the comparison result. The error amplifying part can integrate the error between the input signal and the feedback signal over time. The amplifying part may have a computing part that computes the difference between the signal output from the output terminal and the common signal and outputs the computation result as the amplified signal. The feedback part can use the amplified signal generated between the output terminal and the common terminal as a differential signal and output a differential signal obtained by attenuating the input differential signal by the prescribed attenuation rate as the feedback signal. In this case, the error amplifying part can amplify the difference between the differential signal output as the feedback signal from the feedback part and the differential signal input as the input signal.

Another aspect of the present invention is an amplification method having a first amplification processing that amplifies a first audio signal to supply a first output signal, a second amplification processing that amplifies a second audio signal to supply a second output signal, and a common signal generation processing that generates a common signal used as a reference signal for the first and second output signals. The first amplification processing has a first subtraction step that generates a first difference signal as the difference between the first audio signal and a first feedback signal. A first integration step integrates the first difference signal. A second subtraction step generates a second difference signal as the difference between the first output signal and the common signal. A first feedback signal generating step that generates the first feedback signal based on the second difference signal. A second application processing has a third subtraction step that generates a third difference signal as the difference between the second audio signal and a second feedback signal. A second integration step integrates the third difference signal. A fourth subtraction step generates a fourth difference signal as the difference between the second output signal and the common signal. A second feedback signal generating step generates the second feedback signal based on the fourth signal. The common signal generating process step has an averaging step that generates the average signal of the first and second audio signals and a common signal generating step that generates the common signal based on the average signal.

In this amplification method, the first feedback generating step may include a first multiplication step that multiples the second difference signal by ½, and the second feedback signal generating step may include a second multiplication step that multiplies the fourth difference signal by ½.

This first amplification processing may also have a first comparison step that compares the integrated signal of the first difference signal with a prescribed reference value and generates the first output signal as a binary signal, and the second amplification processing may also have a second comparison step that compares the integrated signal of the third difference signal with a prescribed reference value and generates the second output signal as a binary signal. Moreover, the common signal generating step may have a fifth subtraction step that generates a fifth difference signal as the difference between the average signal and the common signal, a third integration step that integrates the fifth difference signal, and a third comparison step that compares the integrated signal of the fifth difference signal with a prescribed reference value and generates the common signal as a binary signal.

In addition, the common signal generating step may have a third comparison step that compares the average signal with a prescribed reference value and generates the common signal as a binary signal, and the average signal is generated based on the integrated signal of the first difference signal and the integrated signal of the third difference signal. This amplification method may also have a first, a second, and a third filter processing that perform low-pass filtering with respect to the first output signal, second output signal, and common signal, respectively.

### BRIEF DESCRIPTION OF THE DRAWINGS

FIG. 1 shows a configuration example of an amplifier for a headphone disclosed in the first embodiment of the present invention;

FIG. 2 shows a configuration example of an amplifier for a headphone disclosed in the second embodiment of the present invention;

FIG. 3 shows a configuration example of an amplifier for a headphone disclosed in the third embodiment of the present invention;

FIG. 4 shows a configuration example of an amplifier for a headphone disclosed in the fourth embodiment of the present invention;

FIG. 5 shows a first example of the general configuration of an amplifier for a headphone; and

FIG. 6 shows a second example of the general configuration of an amplifier for a headphone.

### REFERENCE NUMERALS AND SYMBOLS AS SHOWN IN THE DRAWINGS

In the figures 100, 100A, 100C, 200, 200A, 200C represent an amplifying part, 300, 300A, 300B, 300C a common signal generating part, 101, 103, 106, 107, 201, 203, 206, 207, 302 a computing part, 102, 108, 202, 208, 303 an integrating part, 104, 110, 204, 210 a feedback part, 105, 109, 205, 209, 304, 306 a comparator, 301, 305 an averaging part, 401, 402 a speaker, and 501-503 a filter

### DESCRIPTION OF THE EMBODIMENTS

According to the present invention, the upper limit on the amplitude of an amplified signal can be increased without raising the power supply voltage by changing the level at the common terminal corresponding to the input signal.

Embodiment 1

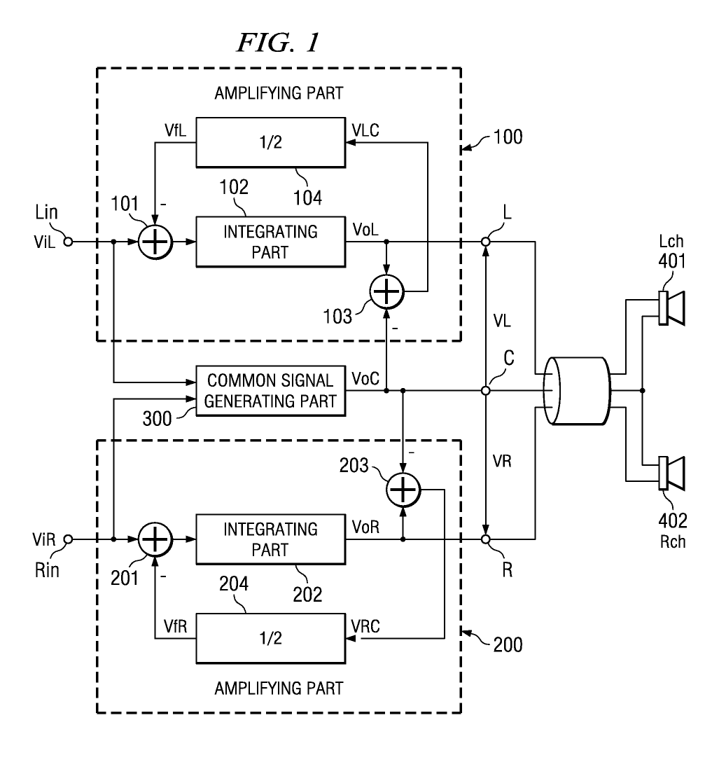

FIG. 1 shows a configuration example of an amplifier for a headphone disclosed in the first embodiment of the present invention. The amplifier shown in FIG. 1 has amplifying parts 100 and 200 and common signal generating part 300. Amplifying parts 100 and 200 are an embodiment of the amplifying part disclosed in the present invention. Common signal generating part 300 is an embodiment of the signal generating part disclosed in the present invention.

The amplifier shown in FIG. 1 is connected to a headphone via three terminals (L, C, R). Audio signal VL supplied to the left speaker 401 of the headphone is generated between output terminal L and common terminal C. Audio signal VR supplied to the right speaker 402 of the headphone is generated between output terminal R and common terminal C.

[Amplifying Part 100]

Amplifying part 100 amplifies left channel audio signal ViL input to input terminal Lin and outputs the amplified signal from output terminal L. As shown in FIG. 1, amplifying part 100 has computing parts 101 and 103, feedback part 104, and integrating part 102. The circuit including computing part 101 and integrating part 102 is an embodiment of the error amplifying part of the present invention. Feedback part 104 is an embodiment of the feedback part of the present invention. Computing part 103 is an embodiment of the computing part of the present invention. Computing part 101 computes the error ‘ViL−VfL’ between audio signal ViL input to input terminal Lin and feedback signal VfL output from feedback part 104. Integrating part 102 integrates error ‘ViL−VfL’ computed by computing part 101 over time. The integration result of integrating part 102 is output as signal VoL to output terminal L. Computing part 103 computes difference ‘VoL−VoC’ between signal VoL output from integrated part 102 and common signal VoC output from common signal generating part 300 and outputs the computation result as signal VLC. Signal VLC has the same amplitude as audio signal VL supplied to the left speaker 401. Feedback part 104 attenuates the amplitude of signal VLC output from computing part 103 by one half and outputs the obtained signal as feedback signal VfL. Feedback signal VfL is equivalent to a signal obtained by multiplying coefficient “½” with the AC component of signal VLC.

[Amplifying Part 200]

Amplifying part 200 amplifies right channel audio signal ViR input to input terminal Rin and outputs the amplified signal from output terminal R. For example, as shown in FIG. 1, amplifying part 200 has computing parts 201 and 203, feedback part 204, and integrating part 202. The circuit including computing part 201 and integrating part 202 is an embodiment of the error amplifying part of the present invention. Feedback part 204 is an embodiment of the feedback part in the present invention. Computing part 203 is an embodiment of the computing part in the present invention. Computing part 201 computes error ‘ViR−VfR’ between audio signal ViR input to input terminal Rin and feedback signal VfR output from feedback part 204. Integrating part 202 integrates error ‘ViR−VfR’ computed by computing part 201 over time and outputs the result as signal VoR to output terminal R.

Computing part 203 computes difference ‘VoR−VoC’ between signal VoR output from integrating part 202 and common signal VoC output from common signal generating part 300 and outputs the computation result as signal VRC. Signal VRC has the same amplitude as audio signal VR supplied to the right speaker 402. Feedback part 204 outputs a signal obtained by attenuating the amplitude of signal VRC output from computing part 203 by one half as feedback signal VfR. Feedback signal VfR is equivalent to a signal obtained by multiplying the AC component of signal VRC by coefficient ‘½’.

[Common Signal Generating Part 300]

Common signal generating part 300 generates common signal VoC corresponding to the average of audio signals ViL and ViR. Said common signal VoC changes the level at common terminal C to increase the amplitudes of audio signals VL and VR supplied to the headphone. In the following, the operation of the amplifier with the configuration shown in FIG. 1 will be explained. In the following explanation, for example, the amplifier shown in FIG. 1 is operated by a single power supply voltage VDD. Also, the DC components of the input audio signals ViL, ViR are set to voltage ‘VDD/2’ as shown in the following equations.

[Mathematical Formula 1]
ViL=viL+VDD/2 1
ViR=viR+VDD/2 2

In the aforementioned equations, ‘viL’ is the AC component of audio signal ViL, while ‘viR’ is the AC component of audio signal ViR. In each circuit inside the amplifier, signal processing is carried out with voltage ‘VDD/2’ used as the reference level. In other words, in amplifying parts 100, 200, with reference level ‘VDD/2’ used as a signal value of zero, subtraction, integration, multiplication by coefficient ‘½’ of the signals are carried out. Common signal VoC shown below is obtained in common signal generating part 300.

[Mathematical Formula 2]
VoC=−(viL+viR)/2+(VDD/2) 3

Common signal VoC shown in equation 3 is obtained by reversing the polarity of the average of audios signals ViL and ViR if voltage ‘VDD/2’ is taken as a signal value of zero. When the amplitudes of AC components viL, viR of the audio signals reach a maximum, that is, ‘VDD/2’, according to equation 3, the amplitude of common signal VoC also reaches a maximum, that is, ‘VDD/2’.

It is assumed that the amplification rates of amplifying parts 100, 200 are both fixed at ‘1’. In this case, since audio signals ViL, ViR are equal to the output signals VoL, VoR of amplifying parts 100, 200, signal VL between terminals L-C and signal VR between terminals R-C become the following.

[Mathematical Formula 3]
VL=(3/2)viL+(1/2)viR 4
VR=(3/2)viR+(1/2)viL 5

According to equations 4, 5, since ‘VL=2×viL’, ‘VR=2×viR’ is valid when signals viL and viR are in phase, output audio signals VL, VR have amplitudes twice that of input audio signals viL, viR. If the upper limit on the amplitudes of audio signals viL, viR is ‘VDD/2’, the upper limit on the amplitude of signals VL, VR is twice as much, that is, ‘VDD’.

As described above, by using the amplifier shown in FIG. 1, when the level at common terminal C is changed corresponding to the average of input audio signals (ViL, ViR) to increase the amplitudes of the output audio signals (VL, VR), the amplitudes of the audio signals (VL, VR) supplied to the headphone can be increased compared with the case when the level at common terminal C is kept constant. Also, the upper limit on the amplitude of audio signals (VL, VR) can be increased without raising the power supply voltage.

However, under the condition that the amplification rates of amplifying parts 100, 200 are fixed at ‘1’, in order double the upper limit of the amplitude, the input audio signals viL and viR must be in phase. If audio signals viL and viL are out of phase, ‘VL=viL’, ‘VR=viR’ become valid according to equations 4, 5. As a result, the output audio signals VL, VR have the same amplitudes as the input audio signals viL, viR, and the upper limit on the amplitude is ‘VDD/2’.

In the amplifier shown in FIG. 1, for example, the feedback circuit in the area encircled by the dotted line is set inside amplifying parts 100, 200. In amplifying part 100, the error ‘ViL−VfL’ between feedback signal VfL obtained by attenuating the amplitude of the output signal VLC of computing part 103 by one half in feedback part 104 and the input audio signal ViL is integrated in integrating part 102. The integration result is output as signal VoL. When the input audio signal ViL becomes larger than feedback signal VfL, error ‘ViL−VfL’ increases positively, and the integration result, that is, signal VoL also increases positively. As a result, signal VLC of computing part 103 increases positively, and feedback signal VfL also increases positively in proportion to it. Therefore, increase of error ‘ViL−VfL’ is restrained. On the other hand, when the input audio signal ViL is smaller than feedback signal VfL, since feedback signal VfL increases negatively, the increase in error ‘ViL−VfL’ is also restrained in this case. Depending on this negative feedback, feedback signal VfL is controlled to become the same signal as the input audio signal ViL, and the output audio signal VL is controlled to have an amplitude twice that of the input audio signal ViL. The same occurs for amplifying part 200. The output audio signal VR is controlled to have an amplitude twice that of the input audio signal ViR.

As described above, when negative feedback control is performed such that the output audio signals (VL, VR) have amplitudes twice those of the input audio signals (ViL, ViR), the upper limit on the amplitude of audio signals (VL, VR) supplied to the headphone can be increased without raising the power supply voltage or depending on the phase relationship of the input audio signals (ViL, ViR).

Also, since the DC gain of integrating part 102 is very large, the DC signal component of error ‘ViL−VfL’ output from computing part 101 is almost zero (‘VDD/2’ as the voltage value). Consequently, the input audio signal ViL and the feedback signal VfL have the same DC signal component. Since the DC signal component of audio signal ViL is zero, the DC signal component of feedback signal VfL is also zero.

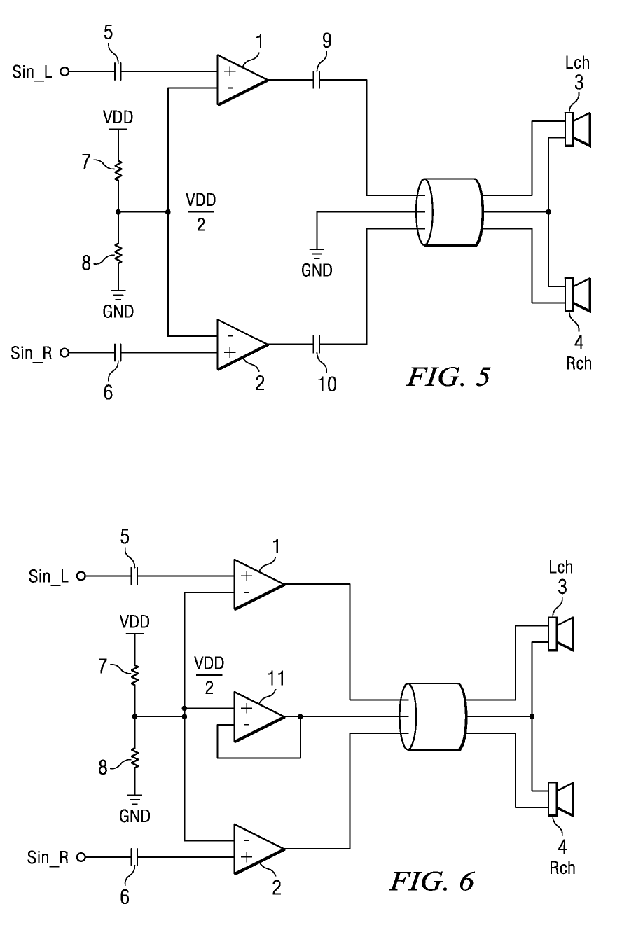

The fact that the DC signal component of feedback signal VfL is zero means that the DC signal component of signal VLC output from computing part 103 is zero. That is, the DC voltage of signal VoL output from integrated part 102 and the DC voltage of common signal VoC are equal to each other and both are ‘VDD/2’. As a result, audio signal VL generated between terminals L-C becomes an AC signal containing no DC voltage. The same occurs for the circuit block of the right channel. Depending on the action of the feedback circuit including integrating part 202, audio signal VR becomes an AC signal containing no DC current. Consequently, the capacitors used for DC cutoff in the amplifier shown in FIG. 5 can be omitted from the amplifier shown in FIG. 1.

In the amplifier shown in FIG. 5, capacitors 9, 10 for DC cutoff determine the low cutoff frequency of the audio signals. Since the input impedance of the speaker is only about 8 ohms, the electrostatic capacitances of capacitors 9, 10 are required to be several hundred μF in order to keep the low cutoff frequency at tens of Hz. Since large-capacitance capacitors can be omitted by using the amplifier shown in FIG. 1, the size and cost of the device can be reduced.

Embodiment 2

In the following, the second embodiment of the present invention will be explained. In the amplifier concerning the second embodiment, D level amplification which generates a pulse signal is conducted.

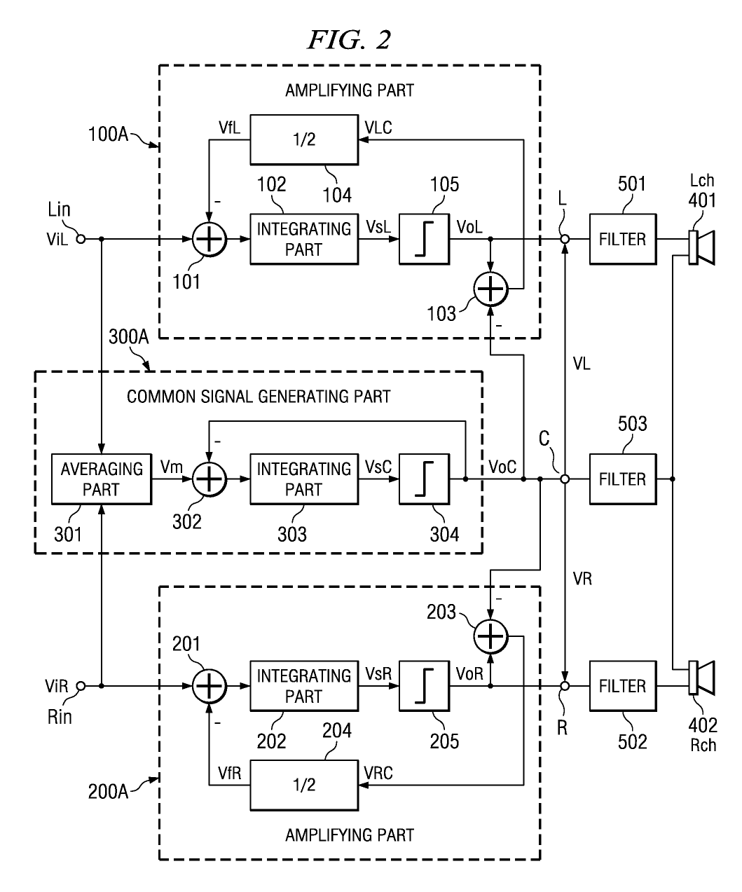

FIG. 2 shows a configuration example of the amplifier used for a headphone disclosed in the second embodiment of the present invention. The amplifier shown in FIG. 2 has amplifying parts 100A and 200A and common signal generating part 300A. Amplifying parts 100A and 200A are an embodiment of the amplifying part disclosed in the present invention. Common signal generating part 300A is an embodiment of the common signal generating part in the present invention. The amplifier shown in FIG. 2 is connected to speakers 401 and 402 of a headphone via three terminals (L, C, R) in the same way as the amplifier shown in FIG. 1.

However, since the signal output from the amplifier shown in FIG. 2 to the headphone is a pulse signal, filters 501, 502, 503 used for eliminating high-frequency components are adopted in the example shown in FIG. 2. In other words, filter 501 is arranged in the signal wire that connects output terminal L and speaker 401, filter 502 is arranged in the signal wire that connects output terminal R and speaker 402, and filter 503 is connected in the signal wire that connects common terminal C and speakers 401, 402.

[Amplifying Part 100A]

Amplifying part 100A is obtained by adding comparator 105 to amplifying part 100 shown in FIG. 1. Comparator 105 compares signal VsL output as the integration result from integrating part 102 with a prescribed reference value and outputs signal VoL of high level or low level corresponding to the comparison result. The output signal VoL of comparator 105 is output to output terminal L and is supplied to computing part 103 and feedback part 104.

[Amplifying Part 200A]

Amplifying part 200A is obtained by adding comparator 205 to amplifying part 200 shown in FIG. 1. Comparator 205 compares signal VsR output as the integration result from integrating part 202 with a prescribed value and outputs signal VoR of high level or low level corresponding to the comparison result. The output signal VoR of comparator 205 is output to output terminal R and is supplied to computing part 203 and feedback part 204.

[Common Signal Generating Part 300A]

Common signal generating part 300A generates a pulse common signal VoC corresponding to the average of the input audio signals ViL and ViR and outputs it to common terminal C. Common signal generating part 300A has averaging part 301, computing part 302, integrating part 303, and comparator 304 as shown in FIG. 2.

Averaging part 301 computes the average of the input audio signals ViL and ViR and outputs the computation result as signal Vm. Computing part 302 computes the difference ‘Vm−VoC’ between signal Vm output from averaging part 301 and common signal VoC. Integrating part 303 integrates difference ‘Vm−VoC’ computed by computing part 302 over time and outputs the integration result as signal VsC. Comparator 304 compares signal VsC of the integration result output from integrating part 303 with a prescribed value and outputs common signal VoC of high level or low level corresponding to the comparison result. Common signal VoC is output to common terminal C and supplied to computing part 302.

In the following, the operation of the amplifier with the configuration shown in FIG. 2 will be explained. In the following explanation, for example, the amplifier shown in FIG. 2 is operated by a single power supply voltage VDD.

Also, the DC voltage of the input audio signals ViL, ViR is set to voltage ‘VDD/2’ as shown in said equations 1, 2. In each circuit inside the amplifier, signal processing is carried out with voltage ‘VDD/2’ used as the reference level. In other words, in amplifying parts 100A, 200A, with reference level ‘VDD/2’ used as a signal value of zero, subtraction, integration, and multiplication by coefficient ‘½’ of the signals are carried out. Signal Vm is generated as shown below in averaging part 301 of common signal generating part 300A.

[Mathematical Formula 4]
Vm=−(viL+viR)/2+(VDD/2) 6

Signal Vm shown in equation 6 is equivalent to common signal VoC shown in equation 3. Signal Vm is obtained by reversing the polarity of the average of audio signals ViL and ViR if voltage ‘VDD/2’ is taken as a signal value of zero. When the amplitudes of AC components viL, viR of the audio signals reach the maximum, that is, ‘VDD/2’, according to equation 6, the amplitude of signal Vm also reaches a maximum, that is, ‘VDD/2’.

The comparators 105, 205, 304 included in the amplifier operate with voltage ‘VDD/2’ used as the threshold value. In other words, when the input signal is higher than voltage ‘VDD/2’, voltage ‘VDD’ is output. When it is lower than voltage ‘VDD/2’, voltage ‘zero’ (ground potential GND) is output.

When the frequency of the pulse signal component included in common signal VoC is higher than the frequency of the audio band (such as 20 Hz-20 kHz), the gain of integrating part 303 with respect to the pulse component is very small compared with the gain with respect to the signal component in the audio band. In other words, in the feedback circuit 302, 303, 304 including integrating part 303, negative feedback control with respect to the signal component of the audio band is mainly performed, while no control is performed for the pulse component. Consequently, the signal component of the audio band included in the pulse common signal Vo is controlled to be almost equal to signal Vm output from averaging part 301.

When the voltages of input audio signals ViL, ViR are both raised, according to equation 6, the voltage of output signal Vm of averaging part 301 falls to the negative side. Consequently, as a result of the operation of the feedback circuit 302, 303, 304, the voltage of the signal component of the audio band included in common signal Vo also falls to the negative side like signal Vm.

On the other hand, when the voltages of input audio signals ViL, ViR are both raised, the voltages of signals VsL, VsR output from integrating parts 102, 202 both increase. When the voltages of signals VsL, VsR increase, the high level periods of pulse signals VoL, VoR output from comparators 105, 205 increase. Consequently, the voltages of the signal components of the audio band included in pulse signals VoL, VoR increase.

On the other hand, when the voltages of the input audio signals ViL, ViR both decrease, the voltages of the signal components of the audio band included in signals VoL, VoR decrease, and the voltage of the signal component of the audio band included in common signal Vo increases. That is, when the input audio signals ViL, ViR vary in phase, the voltage of the audio band component included in common signal VoC varies in opposite phase versus the voltages of the audio band included in signals VoL, VoR.

Consequently, by using the amplifier shown in FIG. 2, the level at common terminal C is changed in a pulsating manner corresponding to the average of the input audio signals (ViL, ViR) to increase the amplitudes of the signal components of the audio band included in signals (VL, VR) supplied to the headphone. In this way, the amplitudes of the audio signals supplied to the headphone can be increased compared with the case when common signal VoC is kept at a constant voltage (such as ‘VDD/2’). Also, the upper limit on the amplitude of the audio signal supplied to the headphone can be increased.

Also, when the frequencies of the pulse components included in signal VoL output from comparator 105 and signal VoR output from comparator 205 are much higher than the frequency of the audio band, in the feedback circuits of amplifying parts 100A and 200A, negative feedback with respect to the signal component of the audio band is mainly controlled, while the pulse component is not controlled. Consequently, the operation of amplifying parts 100A and 200A with respect to the audio band component is almost the same as for amplifying parts 100 and 200 explained above.

In other words, in amplifying part 100A, the signal component of the audio band included in output audio signal VL generated between terminals L-C is controlled to have an amplitude twice that of the input audio signal ViL. In amplifying part 200A, the signal component of the audio band included in output audio signal VR generated between terminals R-C is controlled to have an amplitude twice that of the input audio signal ViR.

Consequently, by using the amplifier shown in FIG. 2, when the negative feedback is controlled such that the signal components of the audio band included in the output audio signals (VL, VR) have amplitudes twice those of the input audio signals (ViL, ViR), the upper limit on the amplitude of the audio signal supplied to the headphone can be increased without raising the power voltage and without depending on the phase relationship of the input audio signals (ViL, ViR).

Also, the DC signal component input to integrating part 102 becomes almost zero (‘VDD/2’ as voltage value), and the DC signal component in the input audio signal ViL is also set at zero. Therefore, the DC signal component of feedback signal VfL becomes zero. The fact that the DC signal component of feedback signal VfL becomes zero means that the DC signal component of signal VLC output from computing part 103 becomes zero. That is, the DC voltage of signal VoL output from comparator 105 is equal to the DC voltage of common signal VoC output from comparator 304. This DC voltage is ‘VDD/2’. As a result, pulse signal VL generated between terminals L-C is an AC signal containing no DC voltage. Similarly, depending on the action of the feedback circuit (amplifying part 200A) including integrating part 202, pulse signal VR becomes an AC signal containing no DC voltage. Consequently, the capacitors used for DC cutoff in the amplifier shown in FIG. 5 can be omitted from the amplifier shown in FIG. 2.

Embodiment 3

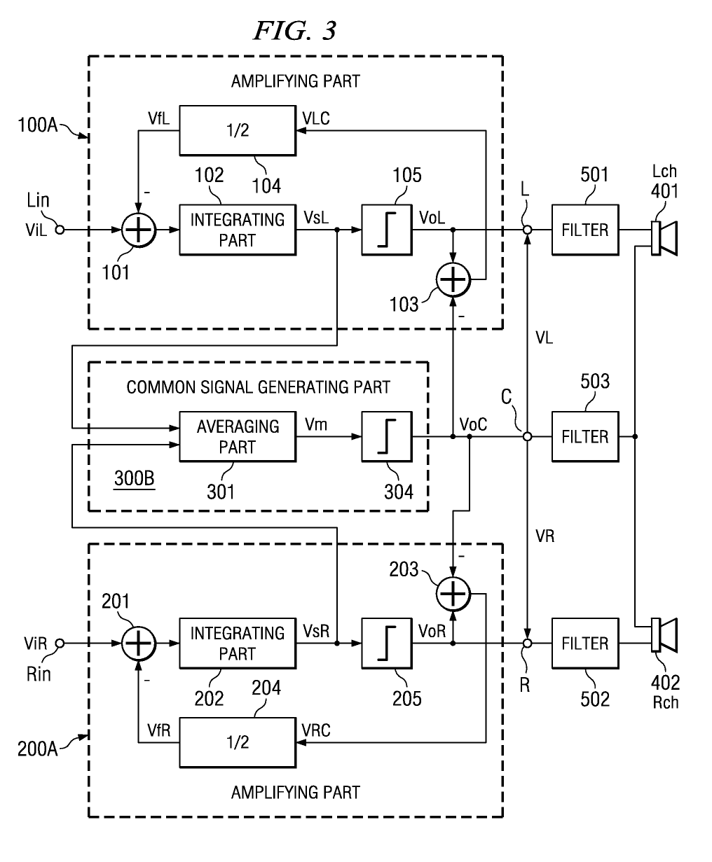

In the following, the third embodiment of the present invention will be explained. FIG. 3 shows a configuration example of the amplifier used for a headphone disclosed in the third embodiment of the present invention. The amplifier shown in FIG. 3 has amplifying parts 100A and 200A and common signal generating part 300B.

Amplifying parts 100A and 200A have the same constituent elements represented by the same symbols as shown in FIG. 2. For common signal generating part 300B, computing part 302 and integrating part 303 are removed from common signal generating part 300A in the amplifier shown in FIG. 2. Amplifying parts 100A and 200A are an embodiment of the amplifying part of the present invention. Common signal generating part 300B is an embodiment of the common signal generating part of the present invention. The circuit including computing part 101 and integrating part 102 and the circuit including computing part 201 and integrating part 202 are an embodiment of the error amplifying part in the present invention. Feedback parts 104 and 204 are an embodiment of the feedback part of the present invention. Computing parts 103 and 203 are an embodiment of the computing part of the present invention. Comparators 105, 205 are an embodiment of the first pulse generating part of the present invention. Comparator 304 is an embodiment of the second pulse generating part of the present invention.

Like the amplifier shown in FIG. 2, the amplifier shown in FIG. 3 is connected to the two speakers 401, 402 of a headphone via three terminals (L, C, R) and three filters 501, 503, 502 used for eliminating high-frequency components. Averaging part 301 calculates the average of output signal VsL of integrating part 102 and output signal VsR of integrating part 202 and outputs the computation result as signal Vm. When the amplifier shown in FIG. 3 is operated by a single power supply voltage VDD, averaging part 301 outputs signal Vm shown below.

[Mathematical Formula 5]
Vm=−(VsL+VsR)/2+(VDD/2) 7

Common signal VoC shown in equation 7 is obtained by reversing the polarity of the average of signals VsL and VsR if voltage ‘VDD/2’ is taken as a signal value of zero. Comparator 304 compares signal Vm output from averaging part 301 with a prescribed threshold value, generates common signal VoC of high level or low level corresponding to the comparison result, and outputs it to common terminal C. When the amplifier shown in FIG. 3 operates at a single power supply voltage VDD, comparator 304 compares the output signal Vm of averaging part 301 with, for example, ‘VDD/2’. If signal Vm is higher than voltage ‘VDD/2’, voltage ‘VDD’ is output as high level. If signal Vm is lower than ‘VDD/2’, voltage ‘zero’ (ground potential GND) is output as low level.

For the operation of the amplifier having the configuration shown in FIG. 3, an example of operating at a single power supply voltage VDD will be explained. When the voltages of the input audio signals ViL, ViR are both increased, the voltages of signals VsL, VSR output from integrated parts 102, 202 both increase. When the voltages of signals VsL, VsR rise, the high level periods of pulse signals VoL, VoR output from comparators 105, 205 increase. Therefore, the voltages of signal components of the audio band included in signals VoL, VoR increase. On the other hand, when the voltages of signals VsL, VsR rise, the voltage of output signal Vm of averaging part 301 falls to the negative side according to equation 7. As a result, the high level period of pulse common signal VoC generated corresponding to signal Vm decreases, and the voltage of the signal component of the audio band included in common signal Vo decreases.

When the voltages of the input audio signals ViL, ViR drop, the voltages of the signal components of the audio band included in signals VoL, VoR decrease, and the voltage of the signal component of the audio band included in common signal Vo increases. That is, when the input audio signals ViL, ViR vary in phase, the voltage of the audio band component included in common signal VoC varies in opposite phase versus the voltages of the audio band included in signals VoL, VoR.

Consequently, by using the amplifier shown in FIG. 3, the level at common terminal C is changed in a pulsating manner corresponding to the average of output signals (VsL, VsR) of integrating parts 102, 202 to increase the amplitudes of the signal components of the audio band included in signals (VL, VR) supplied to the headphone. In this way, the amplitudes of the audio signals supplied to the headphone can be increased compared with the case when common signal VoC is kept at a constant voltage (such as ‘VDD/2’). Also, the upper limit on the amplitude of the audio signal supplied to the headphone can be increased.

Also, like the amplifier shown in FIG. 2, by using the amplifier shown in FIG. 3 and by controlling the negative feedback in amplifying parts 100A, 200A, the upper limit on the amplitude of the audio signal supplied to the headphone can be increased without raising the power voltage and without depending on the phase relationship of the input audio signals (ViL, ViR). In addition, like the amplifier shown in FIG. 2, by using the amplifier shown in FIG. 3, depending on the action of the feedback circuits including integrating parts 102, 202, pulse signals VL and VR become AC signals without any DC voltage. Therefore, the capacitors used for cutting off DC components in the amplifier shown in FIG. 5 can be removed.

Embodiment 4

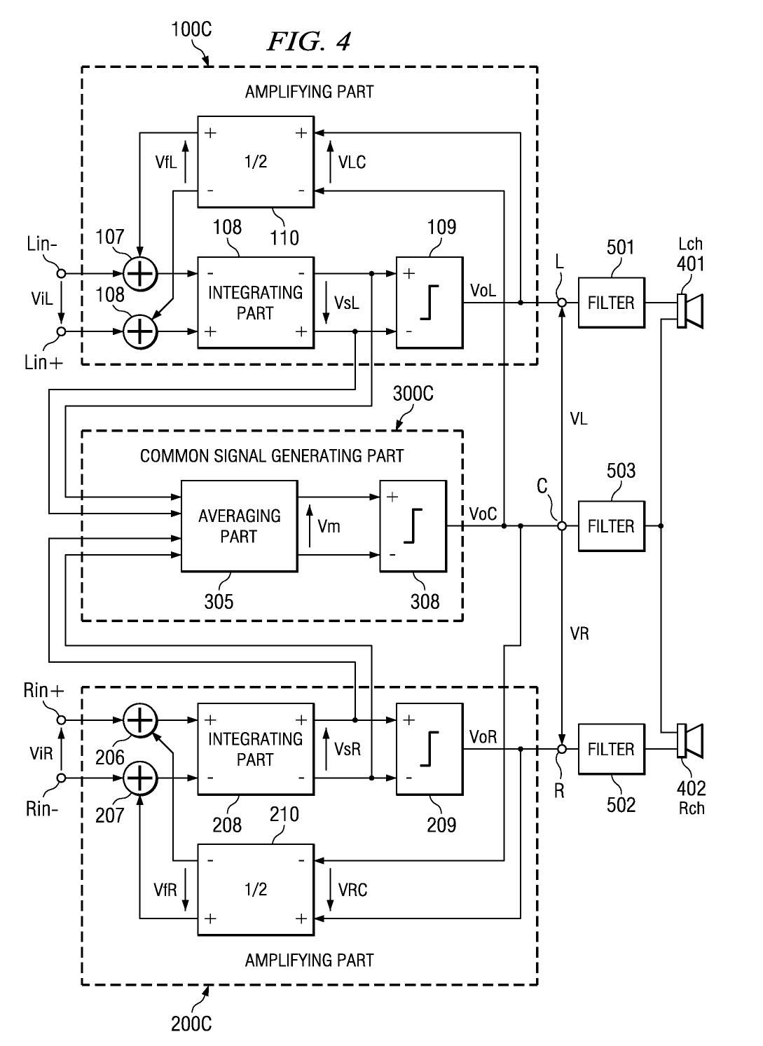

In the following, the fourth embodiment of the present invention will be explained. FIG. 4 shows a configuration example of the amplifier for a headphone disclosed in the fourth embodiment of the present invention. The amplifier shown in FIG. 4 has amplifying parts 100C and 200C and common signal generating part 300C. Amplifying parts 100C and 200C are an embodiment of the amplifying part in the present invention. Common signal generating part 300C is an embodiment of the signal generating part of the present invention. Like the amplifiers shown in FIGS. 2, 3, the amplifier shown in FIG. 4 is connected to the two speakers 401, 402 of a headphone via three terminals (L, C, R) and three filters 501, 503, 502 used for removing high-frequency components.

[Amplifying Part 100C]

Amplifying part 100C converts audio signal ViL of the left channel input as a differential signal to input terminals Lin+ and Lin− into pulse signal VoL, which is output from output terminal L. As shown in FIG. 4, amplifying part 100C has computing parts 106 and 107, integrating part 108, comparator 109, and feedback part 110. The circuit including computing parts 106, 107 and integrating part 108 is an embodiment of the error amplifying part in the present invention. Comparator 109 is an embodiment of the first pulse generating part in the present invention. Feedback part 110 is an embodiment of the feedback part in the present invention. Computing parts 106 and 107 compute error ‘ViL−VfL’ between audio signal ViL input as differential signal and feedback signal VfL generated as a differential signal in feedback part 110. That is, computing part 106 adds the signal on the positive side of audio signal ViL input to input terminal Lin+ and the signal on the negative side of feedback signal VfL output from the negative output terminal of feedback part 110. Computing part 107 adds the signal on the negative side of audio signal ViL input to input terminal Lin− to the signal on the positive side of feedback signal VfL output from the positive output terminal of feedback part 110. Integrating part 108 integrates the error ‘ViL−VfL’ computed by computing parts 106 and 107 over time and outputs the integration result as differential signal VsL. Comparator 109 generates signal VoL, which is high level if differential signal VsL output from integrating part 108 is positive and is low level if differential signal VsL is negative, and outputs it to output terminal L.

When the amplifier shown in FIG. 4 operates at a single power supply voltage VDD, comparator 109 outputs voltage ‘VDD’ as high level and outputs voltage ‘zero’ (ground potential GND) as low level. Feedback part 110 inputs signal VL generated between output terminal L and common terminal C as a differential signal and outputs a differential signal obtained by attenuating the amplitude of the aforementioned differential signal by one half as feedback signal VfL.

[Amplifying Part 200C]

Amplifying part 200C converts the audio signal ViR of the right channel input as a differential signal to input terminal Rin+ and Rin− into a pulse signal VoR, which is output from output terminal R. As shown in FIG. 4, amplifying part 200C has computing parts 206 and 207, integrating part 208, comparator 209, and feedback part 210. The circuit including computing parts 206, 207 and integrating part 208 is an embodiment of the error amplifying part in the present invention. Comparator 209 is an embodiment of the first pulse generating part in the present invention. Feedback part 210 is an embodiment of the feedback part in the present invention. Computing parts 206 and 207 compute error “ViR−VfR’ between audio signal ViR input as a differential signal and feedback signal VfR generated as a differential signal by feedback part 210.

That is, computing part 206 adds the signal on the positive side of audio signal ViR input to input terminal Rin+ to the signal on the negative side of feedback signal VfR output from the negative output terminal of feedback part 210. Computing part 207 adds the signal on the negative side of audio signal ViR input to input terminal Rin− to the signal on the positive side of feedback signal VfR output from the positive output terminal of feedback part 210. Integrating part 208 integrates error ‘ViR−VfR’ computed by computing parts 206 and 207 over time and outputs the integration result as differential signal VsR. Comparator 209 generates signal VoR, which is high level if differential signal VsR output from integrating part 208 is positive and is low level if differential signal VsR is negative, and outputs it to output terminal R. When the amplifier shown in FIG. 4 operates at a single power supply voltage VDD, comparator 209 outputs voltage ‘VDD’ as high level and outputs voltage ‘zero’ (ground potential GND) as low level. Feedback part 210 inputs signal VR generated between output terminal R and common terminal C as a differential signal and outputs a differential signal obtained by attenuating the amplitude of the aforementioned differential signal by one half as feedback signal VfL.

[Common Signal Generating Part 300C]

Common signal generating part 300C generates a pulse common signal VoC corresponding to the average of differential signals VsL and VsR and outputs it to common terminal C. Common signal generating part 300C has averaging part 305 and comparator 306 as shown in FIG. 4. Averaging part 305 computes the average of differential signal VsL output from integrating part 108 and differential signal VsR output from integrating part 208 and outputs the computation result as differential signal Vm. Averaging part 305 outputs signal Vm shown below.

[Mathematic Formula 6]
Vm=−(VsL+VsR)/2 8

Signal Vm shown in equation 8 is obtained by reversing the polarity of the average of differential signals VsL and VsR. Comparator 306 generates a common signal VoC, which is high level if differential signal Vm output from averaging part 305 is positive and is low level if differential signal Vm is negative, and outputs it to common terminal C. When the amplifier shown in FIG. 4 operates at a single power supply voltage VDD, comparator 306 outputs voltage ‘VDD’ as high level and outputs voltage ‘zero’ (ground potential GND) as low level. The amplifier shown in FIG. 4 is equivalent to the aforementioned amplifier shown in FIG. 3 except that the signals (ViL, VfL, VsL, VOL, ViR, VfR, VsR, VoR) processed in the various circuits of the amplifier are replaced by differential signals. Consequently, by using the amplifier shown in FIG. 4, the upper limit on the amplitude of the audio signal supplied to the headphone can be increased without raising the power supply voltage in the same way as the amplifier shown in FIG. 3.

Also, as shown in FIG. 4, since differential signals VL, VR are directly processed by feedback circuits 110, 210, computing parts 103, 203 needed for the amplifier shown in FIG. 3 can be omitted from the amplifier shown in FIG. 4. Also, if an analog circuit is formed in an LSI, in order to reduce the influence of noise coming from the digital circuit, a differential circuit is usually used. Consequently, the circuit with the differential configuration shown in FIG. 4 can be realized without particularly increasing the circuit scale.

Several embodiments of the present invention have been explained above. The present invention, however, is not limited to these embodiments. Various variations are also included. In the aforementioned embodiments, an integrating part is used to amplify the error between the input signal and the feedback signal in the amplifying part. However, it is possible to replace the integrating part with a circuit having various transmission characteristics. In the aforementioned embodiments, a pulse signal is generated by comparator. However, it is also possible to use a circuit that generates a pulse width modulating signal with a certain frequency. In the aforementioned embodiments, the amplifiers are realized in a hardware manner using circuits. The present invention is not limited to this. For example, it is also possible to realize at least some of the functions of the circuits in a software manner using a digital signal processor, etc. The aforementioned embodiments show examples of amplifiers that amplify audio signals of two channels, that is, left and right channels. The present invention is also applicable to amplifiers that amplify audio signals of 3 channels or more. Also, the present invention is not limited to amplification of audio signals. The band of the signals to be amplified is arbitrary.

While the invention has been particularly shown and described with reference in preferred embodiments thereof it is well understood by those skilled in the art that various changes and modifications can be made in the invention without departing from the spirit and scope of the invention as defined by the appended claims.

1. An amplifier generating plural amplified signals corresponding to plural input signals between one common terminal and plural output terminals, comprising:
plural amplifying parts, each of which amplifies one of the plural input signals and outputs the amplified signal to one of the plural output terminals; and
a signal generating part generating a common signal that changes the level at the common terminal corresponding to the average of the plural input signals to increase the amplitudes of the plural amplified signals.

2. The amplifier described in claim 1 wherein each of the amplifying parts has:
an error amplifying part that amplifies the error between the input signal and a feedback signal and outputs the amplified error to an output terminal;
a feedback part that outputs a signal obtained by attenuating the amplitude of the amplified signal generated between the output terminal and the common terminal by a prescribed attenuation rate as the feedback signal; and
negative feedback is controlled to reduce the difference between the input signal and the feedback signal.

3. The amplifier described in claim 1 wherein each of the amplifying parts has:
an error amplifying part that amplifies the error between the input signal and a feedback signal;
a first pulse generating part that generates a first pulse signal corresponding to the signal output from the error amplifying part and outputs the first pulse signal to an output terminal; and
a feedback part that outputs a signal obtained by attenuating the amplitude of the amplified signal generated between the output terminal and the common terminal by a prescribed attenuation rate as the feedback signal;
and wherein negative feedback is controlled to reduce the difference between the input signal and the feedback signal, and
the signal generating part has a second pulse generating part, which generates a second pulse signal corresponding to the average of the output signals of the error amplifying parts included in the plural amplifying parts and outputs the second pulse signal to the common terminal.

4. The amplifier described in claim 3 wherein the first pulse generating part compares the signal output from the error amplifying part with a prescribed threshold value and switches the level of the output signal to a first level or a second level corresponding to the comparison result; and
the second pulse generating part compares the average of the output signal of the error amplifying part included in each of the plural amplifying parts with a prescribed threshold value and switches the level of the output signal to the first or second level corresponding to the comparison result.

5. The amplifier described in claim 2 wherein the error amplifying part integrates the error between the input signal and the feedback signal over time.

6. The amplifier described in claim 2 wherein the amplifying part has a computing part that computes the difference between the signal output from the output terminal and the common signal and outputs the computation result as the amplified signal.

7. The amplifier described in claim 2 wherein the feedback part uses the amplified signal generated between the output terminal and the common terminal as a differential signal and outputs a differential signal obtained by attenuating the input differential signal by the prescribed attenuation rate as the feedback signal; and
the error amplifying part amplifies the difference between the differential signal output as the feedback signal from the feedback part and the differential signal input as the input signal.

8. An amplification method having a first amplification process that amplifies a first audio signal to supply a first output signal, a second amplification process that amplifies a second audio signal to supply a second output signal, and a common signal generation process that generates a common signal used as a reference signal for the first and second output signals, comprising
the first amplification process has a first subtraction step that generates a first difference signal as the difference between the first audio signal and a first feedback signal, a first integration step that integrates the first difference signal, a second subtraction step that generates a second difference signal as the difference between the first output signal and the common signal, and a first feedback signal generating step that generates the first feedback signal based on the second difference signal;
the second application processing has a third subtraction step that generates a third difference signal as the difference between the second audio signal and a second feedback signal, a second integration step that integrates the third difference signal, a fourth subtraction step that generates a fourth difference signal as the difference between the second output signal and the common signal, and a second feedback signal generating step that generates the second feedback signal based on the fourth signal;
the common signal generating process step having an averaging step that generates the average signal of the first and second audio signals and a common signal generating step that generates the common signal based on the average signal.

9. The amplification method described in claim 8 wherein the first feedback generating step includes a first multiplication step that multiples the second difference signal by ½, and
the second feedback signal generating step includes a second multiplication step that multiplies the fourth difference signal by ½.

10. The amplification method described in claim 8 wherein the first amplification process has a first comparison step that compares the integrated signal of the first difference signal with a prescribed reference value and generates the first output signal as a binary signal, and
the second amplification process has a second comparison step that compares the integrated signal of the third difference signal with a prescribed reference value and generates the second output signal as a binary signal.

11. The amplification method described in claim 10 wherein the common signal generating step has a fifth subtraction step that generates a fifth difference signal as the difference between the average signal and the common signal, a third integration step that integrates the fifth difference signal, and a third comparison step that compares the integrated signal of the fifth difference signal with a prescribed reference value and generates the common signal as a binary signal.

12. The amplification method described in claim 10 wherein the common signal generating step has a third comparison step that compares the average signal with a prescribed reference value and generates the common signal as a binary signal; and
the average signal is generated based on the integrated signal of the first difference signal and the integrated signal of the third difference signal.

13. The amplification method described in claim 11 a first, a second, and a third filtering that performs low-pass filtering with respect to the first output signal, second output signal, and common signal, respectively.

14. The amplifier described in claim 3 wherein the error amplifying part integrates the error between the input signal and the feedback signal over time.

15. The amplifier described in claim 4 wherein the error amplifying part integrates the error between the input signal and the feedback signal over time.

16. The amplifier described in claim 3 wherein the amplifying part has a computing part that computes the difference between the signal output from the output terminal and the common signal and outputs the computation result as the amplified signal.

17. The amplifier described in claim 4 wherein the amplifying part has a computing part that computes the difference between the signal output from the output terminal and the common signal and outputs the computation result as the amplified signal.

18. The amplifier described in claim 5 wherein the amplifying part has a computing part that computes the difference between the signal output from the output terminal and the common signal and outputs the computation result as the amplified signal.

19. The amplifier described in claim 3 wherein the feedback part uses the amplified signal generated between the output terminal and the common terminal as a differential signal and outputs a differential signal obtained by attenuating the input differential signal by the prescribed attenuation rate as the feedback signal; and
the error amplifying part amplifies the difference between the differential signal output as the feedback signal from the feedback part and the differential signal input as the input signal.

20. The amplifier described in claim 4 wherein the feedback part uses the amplified signal generated between the output terminal and the common terminal as a differential signal and outputs a differential signal obtained by attenuating the input differential signal by the prescribed attenuation rate as the feedback signal; and
the error amplifying part amplifies the difference between the differential signal output as the feedback signal from the feedback part and the differential signal input as the input signal.
